(19) United States
(12) Patent Application Publication
(10) Pub. No.: US 2026/0075919 A1
(43) Pub. Date: Mar. 12, 2026

(54) SEMICONDUCTOR STRUCTURE AND FORMING METHOD THEREOF

(71) Applicant: NATIONAL TSING HUA UNIVERSITY, Hsinchu City (TW)

(72) Inventors: Tsung-Lin LEE, Taipei City (TW); King-Yuen WONG, Hsinchu City (TW); Shuo-Hung HSU, Hsinchu City (TW)

(21) Appl. No.: 19/046,370

(22) Filed: Feb. 5, 2025

(30) Foreign Application Priority Data
Sep. 12, 2024 (TW) 113134593

(51) Int. Cl. H10D 64/27; H10D 64/01; H10D 64/66

(52) U.S. Cl. CPC H10D 64/518; H10D 64/027; H10D 64/513; H10D 64/669; H10D 64/675

(57) ABSTRACT

A semiconductor structure includes a pad layer, a trench, a gate and two protecting parts. The trench passes through the pad layer along a direction. The gate is in T-shape, and is disposed on the pad layer, and extends into the trench. The gate includes a first part and a second part. The first part is disposed on the pad layer, and includes two side walls and a first metal layer. The second part is connected to the first part, and is located in the trench. The two protecting parts are respectively covered the two side walls, and the first metal layer is disposed between the two protecting parts. Thus, the semiconductor structure can prevent the element characteristics from being affected.

### RELATED APPLICATIONS

This application claims priority to Taiwan Application Serial Number 113134593, filed Sep. 12, 2024, which is herein incorporated by reference.

### BACKGROUND

### Technical Field

The present disclosure relates to a semiconductor structure and a forming method thereof. More particularly, the present disclosure relates to a semiconductor structure with the T-gate and a forming method thereof.

### Description of Related Art

Currently, CMOS process uses a TiN/AlCu alloy/TiN material structure in manufacturing the T-gate. However, if the TiN/AlCu alloy/TiN material structure is used in the gallium nitride process, the AlCu alloy will react with other processes and generate the extended compounds, which will affect the element characteristics.

Accordingly, there is a lack of a semiconductor structure and a forming method thereof on the market currently, which can prevent the AlCu alloy from being exposed during the semiconductor process and affecting the element characteristics. Thus, the relevant industries are looking for the solution.

### SUMMARY

According to one aspect of the present disclosure, a semiconductor structure includes a pad layer, a trench, a gate and two protecting parts. The trench passes through the pad layer along a direction. The gate is in T-shape, and is disposed on the pad layer, and extends into the trench. The gate includes a first part and a second part. The first part is disposed on the pad layer, and includes two side walls and a first metal layer. The second part is connected to the first part, and is located in the trench. The two protecting parts are respectively covered the two side walls, and the first metal layer is disposed between the two protecting parts.

According to another aspect of the present disclosure, a semiconductor structure forming method includes the following steps. Forming a trench by etching a pad layer, and the trench passes through the pad layer along a direction. Depositing a gate on the pad layer, and the gate is in T-shape and extends into the trench. Depositing a protecting layer on the pad layer and the gate. Forming two protecting parts by etching the protecting layer to remove a bottom part and a top part of the protecting layer, the two protecting parts are respectively covered two side walls and a first metal layer of the gate is disposed between the two protecting parts. The gate includes a first part and a second part. The first part is disposed on the pad layer, and includes the two side walls and the first metal layer. The second part is connected to the first part, and is located in the trench.

According to another aspect of the present disclosure, a semiconductor structure includes a pad layer, a trench, a gate and two protecting parts. The trench passes through the pad layer along a direction. The gate is in T-shape, and is disposed on the pad layer, and extends into the trench. The gate includes a first part and a second part. The first part is disposed on the pad layer, and includes two side walls and a first metal layer. The second part is connected to the first part, and is located in the trench. The two protecting parts are respectively covered the two side walls to isolate the first metal layer from an outside.

### BRIEF DESCRIPTION OF THE DRAWINGS

The present disclosure can be more fully understood by reading the following detailed description of the embodiment, with reference made to the accompanying drawings as follows:

FIG. 1 is a cross-sectional schematic view of a semiconductor structure of the 1st embodiment of the present disclosure.

FIG. 2A is a cross-sectional schematic view for showing a first sub-step of an intermediate step of the semiconductor structure forming method according to the 1st embodiment of FIG. 1.

FIG. 2B is a cross-sectional schematic view for showing a second sub-step of the intermediate step of the semiconductor structure forming method according to the 1st embodiment of FIG. 1.

FIG. 2C is a cross-sectional schematic view for showing a third sub-step of the intermediate step of the semiconductor structure forming method according to the 1st embodiment of FIG. 1.

FIG. 2D is a cross-sectional schematic view for showing a fourth sub-step of the intermediate step of the semiconductor structure forming method according to the 1st embodiment of FIG. 1.

FIG. 2E is a cross-sectional schematic view for showing a fifth sub-step of the intermediate step of the semiconductor structure forming method according to the 1st embodiment of FIG. 1.

FIG. 2F is a cross-sectional schematic view for showing a sixth sub-step of the intermediate step of the semiconductor structure forming method according to the 1st embodiment of FIG. 1.

FIG. 3 is a cross-sectional schematic view of a semiconductor structure of the 2nd embodiment of the present disclosure.

FIG. 4A is a cross-sectional schematic view for showing a first sub-step of an intermediate step of the semiconductor structure forming method according to the 2nd embodiment of FIG. 3.

FIG. 4B is a cross-sectional schematic view for showing a second sub-step of the intermediate step of the semiconductor structure forming method according to the 2nd embodiment of FIG. 3.

FIG. 4C is a cross-sectional schematic view for showing a third sub-step of the intermediate step of the semiconductor structure forming method according to the 2nd embodiment of FIG. 3.

FIG. 4D is a cross-sectional schematic view for showing a fourth sub-step of the intermediate step of the semiconductor structure forming method according to the 2nd embodiment of FIG. 3.

FIG. 4E is a cross-sectional schematic view for showing a fifth sub-step of the intermediate step of the semiconductor structure forming method according to the 2nd embodiment of FIG. 3.

FIG. 4F is a cross-sectional schematic view for showing a sixth sub-step of the intermediate step of the semiconductor structure forming method according to the 2nd embodiment of FIG. 3.

### DETAILED DESCRIPTION

The embodiment will be described with the drawings. For clarity, some practical details will be described below. However, it should be noted that the present disclosure should not be limited by the practical details, that is, in some embodiment, the practical details is unnecessary. In addition, for simplifying the drawings, some conventional structures and elements will be simply illustrated, and repeated elements may be represented by the same labels.

In addition, the terms first, second, third, etc. are used herein to describe various elements or components, these elements or components should not be limited by these terms. Consequently, a first element or component discussed below could be termed a second element or component.

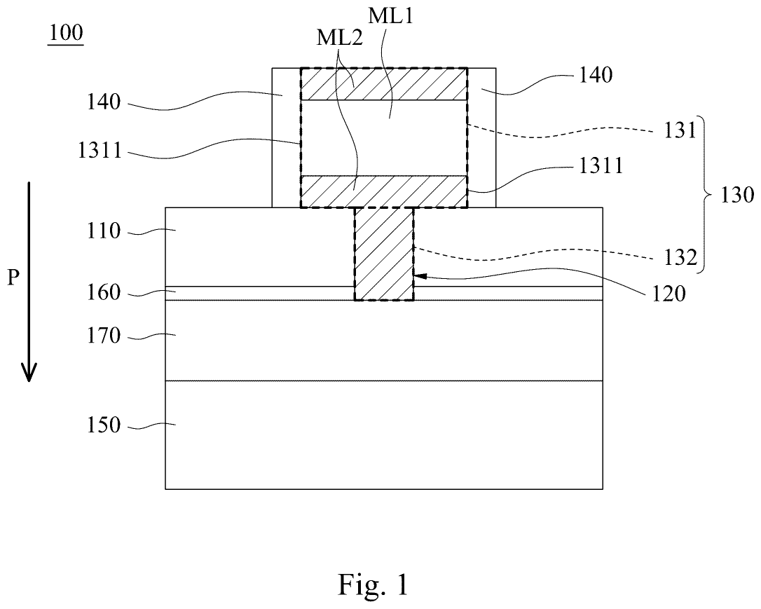

FIG. 1 is a cross-sectional schematic view of a semiconductor structure 100 of the 1st embodiment of the present disclosure. As shown in FIG. 1, the semiconductor structure 100 includes a pad layer 110, a trench 120, a gate 130 and two protecting parts 140. The trench 120 passes through the pad layer 110 along a direction P. The gate 130 is disposed on the pad layer 110, and extends into the trench 120. The protecting parts 140 are respectively disposed on two sides of the gate 130.

It should be noted that, the semiconductor structure 100 can be applied to an integrated circuit (IC) or a part thereof, such as a logic circuit, a resistor, a capacitor, an inductor, a memory (such as a dynamic random access memory (DRAM)), etc. It is to be understood that, some elements of the semiconductor structure 100 are not shown in the FIG. 1, additional elements may be included in other embodiments.

The semiconductor structure 100 can further include a substrate 150, a dielectric layer 160 and a barrier 170. The pad layer 110, the dielectric layer 160 and the barrier 170 are sequentially stacked on the substrate 150. The dielectric layer 160 is disposed below the pad layer 110. The barrier 170 is disposed below the dielectric layer 160, and located between the substrate 150 and the dielectric layer 160. The trench 120 passes through the pad layer 110 and the dielectric layer 160 along the direction P. In the 1st embodiment, the material of the pad layer 110 can be SiO₂; the material of the substrate 150 can be Si; the material of the dielectric layer 160 can be Al₂O₃; the material of the barrier 170 can be GaN, but the present disclosure is not limited thereto.

The gate 130 is in T-shape, and includes a first part 131 and a second part 132. The first part 131 is disposed on the pad layer 110. The second part 132 is connected to the first part 131, and is located in the trench 120.

The gate 130 is formed by stacking a first metal layer ML1 and two second metal layers ML2 along the direction P, the first metal layer ML1 is located between the two second metal layers ML2. The material of the first metal layer ML1 is an AlCu alloy, the material of each of the two second metal layers ML2 is TiN. In the 1st embodiment, the first metal layer ML1 and the two second metal layers ML2 (the upper one of the second metal layers ML2, the first metal layer ML1 and part of the lower one of the second metal layers ML2) are deposited on the pad layer 110 to form the first part 131. The other part of the lower one of the second metal layers ML2 is deposited in the trench 120 to form the second part 132. The second metal layer ML2 below the first metal layer ML1 (the lower one of the second metal layers ML2) is in T-shape, but the present disclosure is not limited thereto.

The first part 131 includes two side walls 1311, the two protecting parts 140 respectively cover the two side walls 1311. The first metal layer ML1 is disposed between the two second metal layers ML2 and the two protecting parts 140, which is for preventing the first metal layer ML1 from being exposed. That is, the two second metal layers ML2 and the two protecting parts 140 can surround the first metal layer ML1 to isolate the first metal layer ML1 from an outside. In the 1st embodiment, each of the two protecting parts 140 is rectangular, but the present disclosure is not limited thereto. In other embodiments, each of the two protecting parts can be circular sector or rounded rectangle.

The material of each of the two protecting parts 140 can be a dielectric material, each of the two protecting parts 140 has the same thickness, and the thickness of each of the two protecting parts 140 is between 2 nm and 50 nm. The dielectric material includes one or more of SiO₂, SiN, TiO₂, Al₂O₃, AlN and AlF₃, but the present disclosure is not limited thereto.

Moreover, the material of each of the two protecting parts 140 can be a metal material, each of the two protecting parts 140 has the same thickness, and the thickness of each of the two protecting parts 140 is between 20 nm and 200 nm. The metal material includes one or more of TiN, TaN, Ni, W, Ta and Ti, but the present disclosure is not limited thereto.

Therefore, the protecting parts 140 are favorable for preventing the first metal layer ML1 (the AlCu alloy) from being exposed during processing so as to reduce the formation of its extended compounds. Further, the protecting parts 140 can also reduce the resistance and the capacitance, improve the controllability of the T-gate over the components, and maintain high-frequency characteristics.

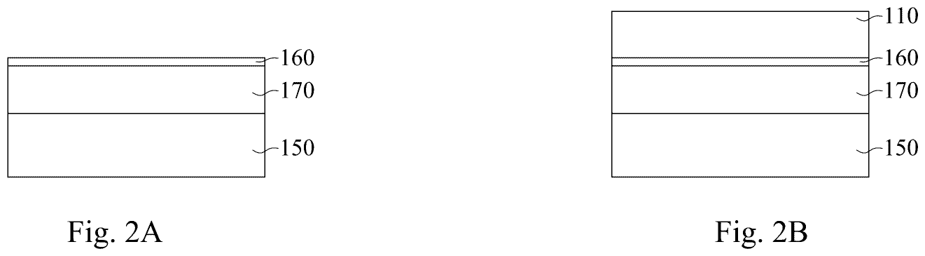

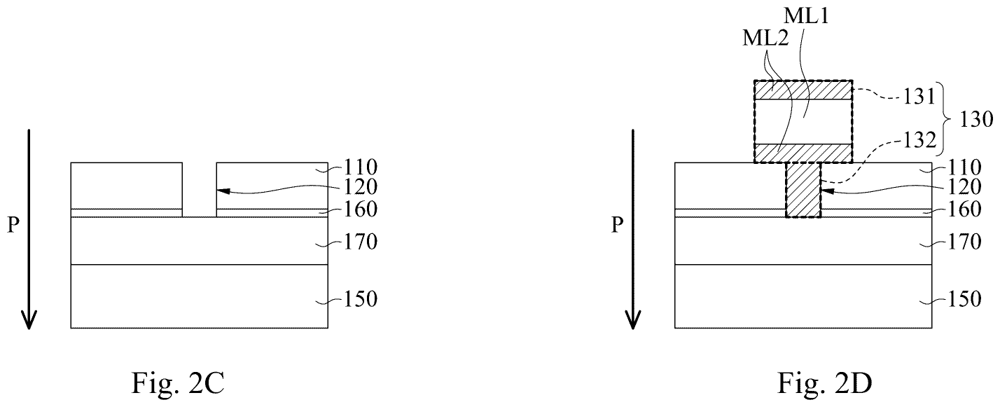

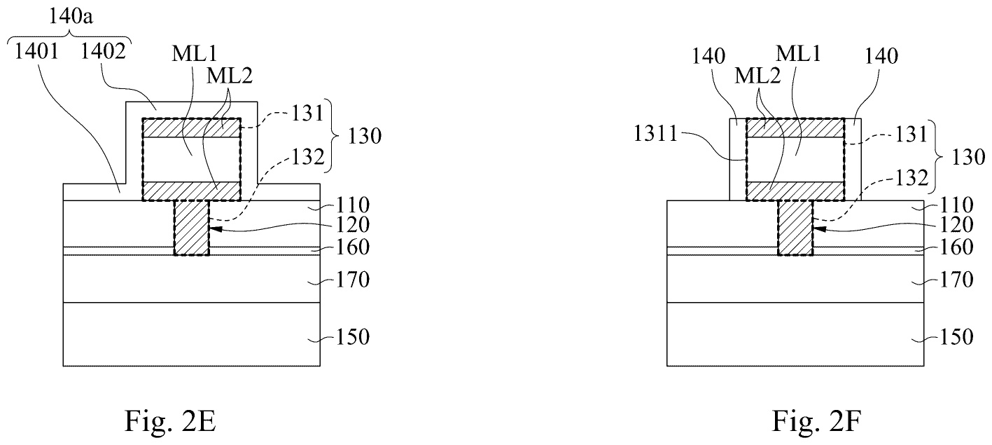

The details of the forming method of the semiconductor structure 100 will be described below. FIG. 2A is a cross-sectional schematic view for showing a first sub-step of an intermediate step of the semiconductor structure 100 forming method according to the 1st embodiment of FIG. 1. FIG. 2B is a cross-sectional schematic view for showing a second sub-step of the intermediate step of the semiconductor structure 100 forming method according to the 1st embodiment of FIG. 1. FIG. 2C is a cross-sectional schematic view for showing a third sub-step of the intermediate step of the semiconductor structure 100 forming method according to the 1st embodiment of FIG. 1. FIG. 2D is a cross-sectional schematic view for showing a fourth sub-step of the intermediate step of the semiconductor structure 100 forming method according to the 1st embodiment of FIG. 1. FIG. 2E is a cross-sectional schematic view for showing a fifth sub-step of the intermediate step of the semiconductor structure 100 forming method according to the 1st embodiment of FIG. 1. FIG. 2F is a cross-sectional schematic view for showing a sixth sub-step of the intermediate step of the semiconductor structure 100 forming method according to the 1st embodiment of FIG. 1.

As shown in FIG. 2A, the barrier 170 and the dielectric layer 160 are sequentially deposited on the substrate 150. As shown in FIG. 2B, after the dielectric layer 160 is formed, the pad layer 110 is deposited on the dielectric layer 160. As shown in FIG. 2C, after the pad layer 110 is formed, the trench 120 is formed by etching the pad layer 110 and the dielectric layer 160. The trench 120 passes through the pad layer 110 and the dielectric layer 160 along the direction P.

As shown in FIG. 2D, after the trench 120 is formed, the gate 130 is deposited on the pad layer 110. The gate 130 is in T-shape and extends into the trench 120. The gate 130 includes the first part 131 and the second part 132. The first part 131 is disposed on the pad layer 110. The second part 132 is connected to the first part 131, and is located in the trench 120. The gate 130 is formed by stacking the first metal layer ML1 and the two second metal layers ML2 along the direction P. In detail, the second part 132 is formed in the trench 120 first then the first part 131 is formed, based on the order of depositing one of the second metal layers ML2, the first metal layer ML1 and the other one of the second metal layers ML2 starting from the trench 120. Part of one of the second metal layers ML2 is deposited in the trench 120 to form the second part 132 first, and the first metal layer ML1 and the two second metal layers ML2 are deposited on the pad layer 110 to form the first part 131.

As shown in FIG. 2E, after the gate 130 is formed, a protecting layer 140a is deposited on the pad layer 110 and the gate 130. As shown in FIG. 2F, after the protecting layer 140a is formed, the two protecting parts 140 are formed by etching the protecting layer 140a to remove a bottom part 1401 and a top part 1402 of the protecting layer 140a. The two protecting parts 140 respectively cover two side walls 1311 of the gate 130, and the first metal layer ML1 is disposed between the two protecting parts 140 so as to prevent the first metal layer ML1 from being exposed.

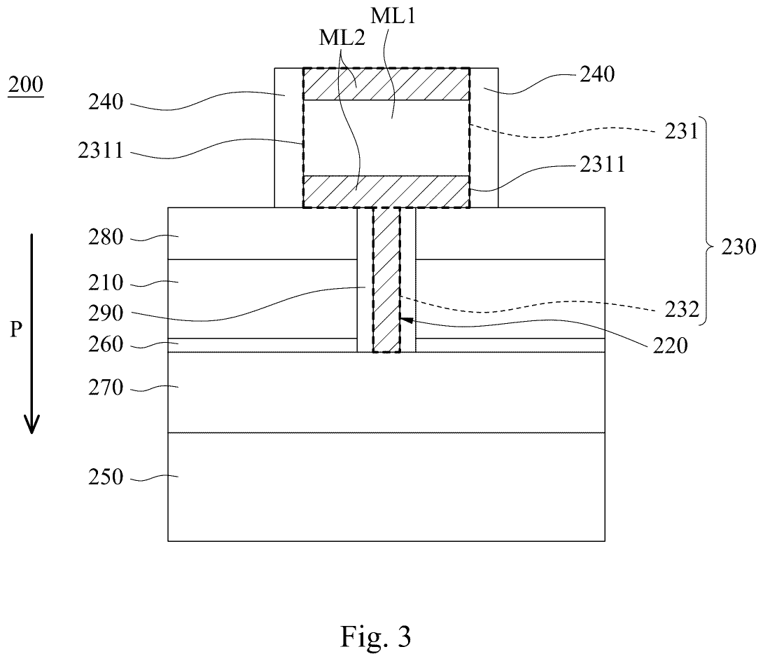

FIG. 3 is a cross-sectional schematic view of a semiconductor structure 200 of the 2nd embodiment of the present disclosure. As shown in FIG. 3, the semiconductor structure 200 includes a pad layer 210, a trench 220, a gate 230, two protecting parts 240, a substrate 250, a dielectric layer 260 and a barrier 270. The trench 220 passes through the pad layer 210 and the dielectric layer 260 along a direction P. The gate 230 is disposed on the pad layer 210, and includes a first part 231 and a second part 232. The first part 231 is disposed on the pad layer 210, the second part 232 is located in the trench 220. The protecting parts 240 are respectively disposed on two sides of the gate 230. The pad layer 210, the dielectric layer 260 and the barrier 270 are sequentially stacked on the substrate 250.

In the 2nd embodiment, the pad layer 210, the gate 230, the two protecting parts 240, the substrate 250, the dielectric layer 260 and the barrier 270 are the same as the pad layer 110, the gate 130, the two protecting parts 140, the substrate 150, the dielectric layer 160 and the barrier 170 of the 1st embodiment respectively, and will not be described again herein.

It should be noted that, the semiconductor structure 200 can be applied to an IC or a part thereof, such as a logic circuit, a resistor, a capacitor, an inductor, a memory (such as a DRAM), etc. It is to be understood that, some elements of the semiconductor structure 200 are not shown in the FIG. 3, additional elements may be included in other embodiments.

The difference between the 2nd embodiment and the 1st embodiment is that the semiconductor structure 200 further includes a sacrificial layer 280 and an isolating layer 290.

The sacrificial layer 280 is disposed on the pad layer 210, and located between the pad layer 210 and the first part 231 of the gate 230, the trench 220 passes through the sacrificial layer 280 along the direction P. The sacrificial layer 280 has a thickness, and the thickness is between 10 nm and 50 nm. The material of the sacrificial layer 280 includes one or more of Al₂O₃ and AlN, but the present disclosure is not limited thereto.

The isolating layer 290 is disposed on an inner side wall of the trench 220 for isolating the pad layer 210 from the second part 232 of the gate 230. The isolating layer 290 has a thickness, and the thickness is between 10 nm and 50 nm. The material of the isolating layer 290 includes one or more of Al₂O₃ and AlN, but the present disclosure is not limited thereto.

Therefore, the isolating layer 290 is favorable for reducing the line width of the gate 230 so as to enhance the high-frequency characteristics of the semiconductor.

Moreover, the sacrificial layer 280 is favorable for protecting the structural stability of the gate 230 so as to prevent the issues with low selectivity during the etching of the isolating layer 290. In detail, by depositing the sacrificial layer 280 with a lower etch rate on the pad layer 210 with a higher etch rate, the sacrificial layer 280 can protect the pad layer 210 from being affected during the layer with the lower etch rate (the sacrificial layer 280) is etched so as to preserve the integrity of the protective structure.

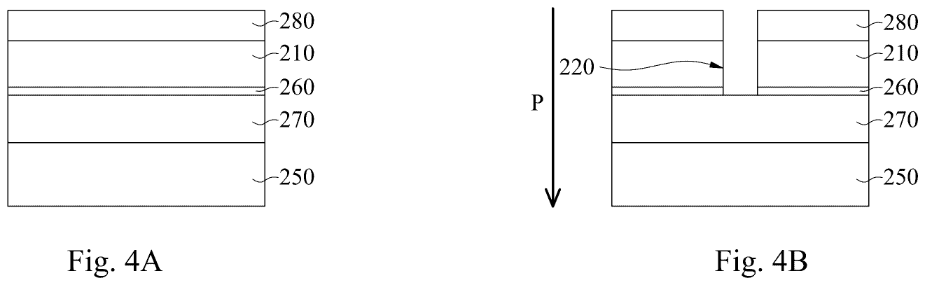

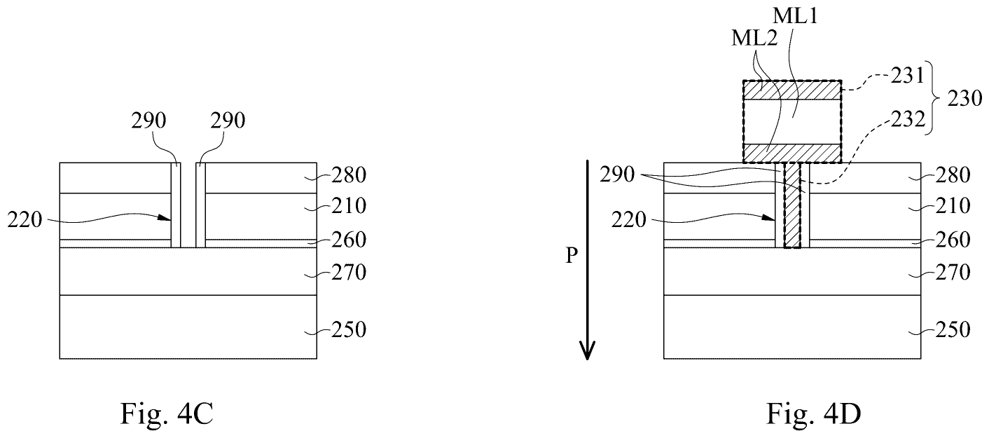

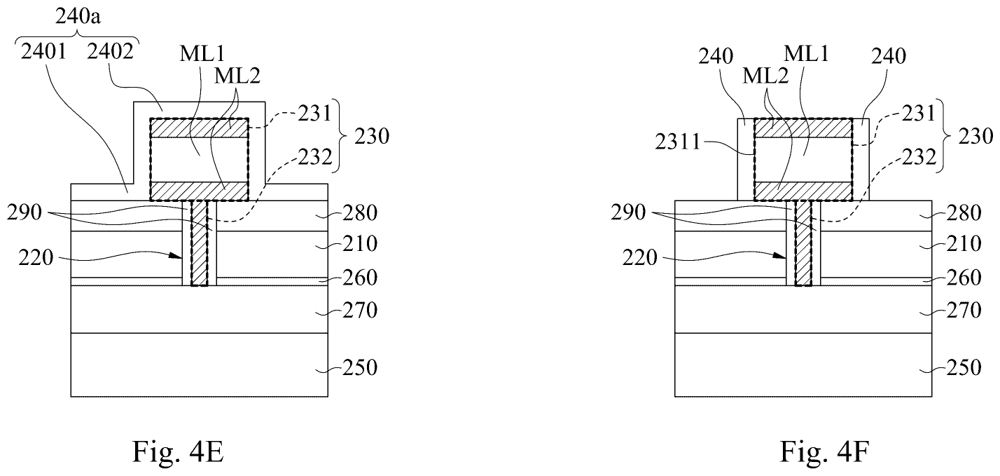

The details of the forming method of the semiconductor structure 200 will be described below. FIG. 4A is a cross-sectional schematic view for showing a first sub-step of an intermediate step of the semiconductor structure 200 forming method according to the 2nd embodiment of FIG. 3. FIG. 4B is a cross-sectional schematic view for showing a second sub-step of the intermediate step of the semiconductor structure 200 forming method according to the 2nd embodiment of FIG. 3. FIG. 4C is a cross-sectional schematic view for showing a third sub-step of the intermediate step of the semiconductor structure 200 forming method according to the 2nd embodiment of FIG. 3. FIG. 4D is a cross-sectional schematic view for showing a fourth sub-step of the intermediate step of the semiconductor structure 200 forming method according to the 2nd embodiment of FIG. 3. FIG. 4E is a cross-sectional schematic view for showing a fifth sub-step of the intermediate step of the semiconductor structure 200 forming method according to the 2nd embodiment of FIG. 3. FIG. 4F is a cross-sectional schematic view for showing a sixth sub-step of the intermediate step of the semiconductor structure 200 forming method according to the 2nd embodiment of FIG. 3.

As shown in FIG. 4A, the barrier 270, the dielectric layer 260 and the pad layer 210 are sequentially deposited on the substrate 250, and the sacrificial layer 280 is deposited on the pad layer 210. As shown in FIG. 4B, after the sacrificial layer 280 is formed, the trench 220 is formed by etching the sacrificial layer 280, the pad layer 210 and the dielectric layer 260. The trench 220 passes through the sacrificial layer 280, the pad layer 210 and the dielectric layer 260 along the direction P.

As shown in FIG. 4C, after the trench 220 is formed, the isolating layer 290 is disposed on the inner side wall of the trench 220. As shown in FIG. 4D, after the isolating layer 290 is formed, the gate 230 is deposited on the sacrificial layer 280. The gate 230 is in T-shape and extends into the trench 220. The gate 230 includes the first part 231 and the second part 232. The first part 231 is disposed on the sacrificial layer 280. The second part 232 is connected to the first part 231, and is located in the trench 220. The gate 230 is formed by stacking the first metal layer ML1 and the two second metal layers ML2 along the direction P. In detail, the second part 232 is formed in the trench 220 first then the first part 231 is formed, based on the order of depositing one of the second metal layers ML2, the first metal layer ML1 and the other one of the second metal layers ML2 starting from the trench 220. Part of one of the second metal layers ML2 is deposited in the trench 220 to form the second part 232 first, and the first metal layer ML1 and the two second metal layers ML2 are deposited on the pad layer 210 to form the first part 231. The isolating layer 290 is configured to isolate the pad layer 210 from the second part 232 of the gate 230, and reduce the line width of the gate 230.

As shown in FIG. 4E, after the gate 230 is formed, a protecting layer 240a is deposited on the sacrificial layer 280 and the gate 230. As shown in FIG. 4F, after the protecting layer 240a is formed, the two protecting parts 240 are formed by etching the protecting layer 240a to remove a bottom part 2401 and a top part 2402 of the protecting layer 240a. The two protecting parts 240 respectively cover two side walls 2311 of the gate 230, and the first metal layer ML1 is disposed between the two protecting parts 240 so as to prevent the first metal layer ML1 from being exposed.

In view of the above, the present disclosure has the following advantages. First, the protecting parts of the present disclosure are favorable for preventing the first metal layer (the AlCu alloy) from being exposed during processing so as to reduce the formation of its extended compounds. Second, the protecting parts of the present disclosure have the advantages of reducing the resistance and the capacitance, improving the controllability of the T-gate over the components, and maintaining high-frequency characteristics. Third, the isolating layer is favorable for reducing the line width of the gate so as to enhance the high-frequency characteristics of the semiconductor, the sacrificial layer is favorable for preventing the issues with low selectivity during the etching of the isolating layer so as to preserve the integrity of the protective structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a pad layer;
a trench passing through the pad layer along a direction;
a gate being in T-shape, disposed on the pad layer, and extending into the trench, the gate comprising:
a first part disposed on the pad layer, and comprising two side walls and a first metal layer; and
a second part connected to the first part, and located in the trench; and
two protecting parts respectively covering the two side walls, and the first metal layer disposed between the two protecting parts.

2. The semiconductor structure of claim 1, wherein the gate is formed by stacking the first metal layer and two second metal layers along the direction, the first metal layer is located between the two second metal layers, and the first metal layer is disposed between the two second metal layers and the two protecting parts, which is for preventing the first metal layer from being exposed;
wherein, a material of the first metal layer is an AlCu alloy, a material of each of the two second metal layers is TiN.

3. The semiconductor structure of claim 1, wherein a material of each of the two protecting parts comprises one or more of SiO₂, SiN, TiO₂, Al₂O₃, AlN and AlF₃.

4. The semiconductor structure of claim 3, wherein a thickness of each of the two protecting parts is between 2 nm and 50 nm.

5. The semiconductor structure of claim 1, wherein a material of each of the two protecting parts comprises one or more of TiN, TaN, Ni, W, Ta and Ti.

6. The semiconductor structure of claim 5, wherein a thickness of each of the two protecting parts is between 20 nm and 200 nm.

7. The semiconductor structure of claim 1, further comprising:
a sacrificial layer disposed on the pad layer, and located between the pad layer and the first part of the gate;
wherein, the trench passes through the sacrificial layer along the direction.

8. The semiconductor structure of claim 7, wherein a thickness of the sacrificial layer is between 10 nm and 50 nm.

9. The semiconductor structure of claim 7, wherein a material of the sacrificial layer comprises one or more of Al₂O₃ and AlN.

10. The semiconductor structure of claim 1, further comprising:
an isolating layer disposed on an inner side wall of the trench for isolating the pad layer from the second part of the gate.

11. The semiconductor structure of claim 10, wherein a thickness of the isolating layer is between 10 nm and 50 nm.

12. The semiconductor structure of claim 10, wherein a material of the isolating layer comprises one or more of Al₂O₃ and AlN.

13. The semiconductor structure of claim 1, further comprising:
a substrate;
a dielectric layer disposed below the pad layer; and
a barrier disposed below the dielectric layer, and located between the substrate and the dielectric layer;
wherein, the trench passes through the dielectric layer along the direction.

14. A semiconductor structure forming method, comprising:
forming a trench by etching a pad layer, wherein the trench passes through the pad layer along a direction;
depositing a gate on the pad layer, wherein the gate is in T-shape and extends into the trench;
depositing a protecting layer on the pad layer and the gate; and
forming two protecting parts by etching the protecting layer to remove a bottom part and a top part of the protecting layer, the two protecting parts respectively covering two side walls and a first metal layer of the gate disposed between the two protecting parts;
wherein, the gate comprises:
a first part disposed on the pad layer, and comprising the two side walls and the first metal layer; and
a second part connected to the first part, and located in the trench.

15. The semiconductor structure forming method of claim 14, wherein the gate is formed by stacking the first metal layer and two second metal layers along the direction, the first metal layer is located between the two second metal layers, and the first metal layer is disposed between the two second metal layers and the two protecting parts, which is for preventing the first metal layer from being exposed;
wherein, a material of the first metal layer is an AlCu alloy, a material of each of the two second metal layers is TiN.

16. The semiconductor structure forming method of claim 14, further comprising:
depositing the pad layer on a dielectric layer; and
forming the trench by etching the pad layer and the dielectric layer, wherein the trench passes through the pad layer and the dielectric layer along the direction.

17. The semiconductor structure forming method of claim 16, further comprising:
depositing a sacrificial layer disposed on the pad layer, wherein the sacrificial layer is located between the pad layer and the first part of the gate; and
forming the trench by etching the sacrificial layer, the pad layer and the dielectric layer, wherein the trench passes through the sacrificial layer along the direction.

18. The semiconductor structure forming method of claim 14, further comprising:
depositing an isolating layer on an inner side wall of the trench for isolating the pad layer from the second part of the gate.

19. A semiconductor structure, comprising:
a pad layer;
a trench passing through the pad layer along a direction;
a gate being in T-shape, disposed on the pad layer, and extending into the trench, the gate comprising:
a first part disposed on the pad layer, and comprising two side walls and a first metal layer; and
a second part connected to the first part, and located in the trench; and
two protecting parts respectively covering the two side walls to isolate the first metal layer from an outside.

20. The semiconductor structure of claim 19, wherein the gate is formed by stacking the first metal layer and two second metal layers along the direction, the first metal layer is located between the two second metal layers, and the first metal layer is disposed between the two second metal layers and the two protecting parts for being isolated from the outside;
wherein, a material of the first metal layer is an AlCu alloy, a material of each of the two second metal layers is TiN.
